(19) United States
(12) Patent Application Publication
(10) Pub. No.: US 2010/0238633 A1
(43) Pub. Date: Sep. 23, 2010

(54) POWER CIRCUIT

(75) Inventors: Gebhard Michenfelder, Lichtenau (DE); Stephan Pauli, Achern (DE)

Correspondence Address: MICHAEL BEST & FRIEDRICH LLP, 100 EAST WISCONSIN AVENUE, MILWAUKEE, WI, 53202, US

(73) Assignee: ROBERT BOSCH GMBH, Stuttgart (DE)

(21) Appl. No.: 12/682,689

(22) PCT Filed: Oct. 27, 2008
(86) PCT No.: PCT/EP2008/064535

§ 371 Date: Apr. 12, 2010

(30) Foreign Application Priority Data
Dec. 21, 2007 (DE) 10 2007 062 167.3

(51) Int. Cl. H05K 7/20

(52) U.S. Cl. 361/717; 361/704

(57) ABSTRACT

A power circuit (10) for activating a drive unit for a wiper system of a motor vehicle has a circuit breaker (14) for activating the drive unit. According to the invention a heat accumulator (16) for absorbing heat accumulating in the circuit breaker (14) when the drive unit is in the blocked state is thermally connected to the circuit breaker (14). In the event of sudden heat generation in the circuit breaker (14) a majority of the resulting heat can be discharged quickly to the heat accumulator (16) such that the circuit breaker (14) can be smaller in size and the power circuit (10) enables use of a higher-ohm circuit breaker (14).

### BACKGROUND OF THE INVENTION

The invention relates to a power circuit for controlling a drive unit for a wiper system of a motor vehicle, it being possible, for example, for the movement of a windshield wiper to be controlled with the aid of said drive unit.

WO 00/46082 discloses a power circuit for controlling a drive unit for a wiper system of a motor vehicle. A circuit breaker is provided for controlling the drive unit.

In a power circuit of this type, the circuit breaker has to be designed in such a way that it does not fail even if the drive unit is blocked, for example if the wipers are frozen to a windshield to be wiped during the winter. In order to be able to reliably absorb the power peaks which occur suddenly when the drive unit is in the blocked state, without failing, the circuit breaker is intentionally over-designed in such a way that the circuit breaker has a correspondingly low-value resistance. This leads to elevated production costs.

The object of the invention is to provide a power circuit for controlling a drive unit for a wiper system of a motor vehicle which permits the use of a higher-resistance circuit breaker.

### SUMMARY OF THE INVENTION

The power circuit according to the invention for controlling a drive unit for a wiper system of a motor vehicle has a circuit breaker for controlling the drive unit, said circuit breaker being thermally connected to a heat accumulator for absorbing heat which is produced in the circuit breaker when the drive unit is in the blocked state.

The heat accumulator can dissipate heat which is suddenly produced in the circuit breaker and, in particular, store said heat at a distance from the circuit breaker. In this case, use is made of the knowledge that a substantial portion of the loading on the circuit breaker when the drive unit is in the blocked state is produced by heat and the design of the circuit breaker depends on the maximum temperature which occurs in the blocked state. The heat accumulator can lower the maximum temperature which occurs in the circuit breaker, and therefore the circuit breaker can be designed to be smaller and the power circuit can use a higher-resistance circuit breaker, as a result of which the production costs for the power circuit are reduced.

Furthermore, the heat accumulator means it is not necessary to achieve a requisite temperature reduction in the circuit breaker solely by natural convection, and therefore heat sinks which are mounted on the circuit breaker are not required. The temperature can be reduced more rapidly by the heat accumulator than with heat sinks, and therefore heat can be dissipated at an early stage and lower maximum temperatures are reached. It is also unnecessary for heat dissipation to be initiated only via connected lines and/or a printed circuit board which have a considerably lower thermal conductivity and/or thermal capacity, and therefore more heat can be dissipated from the circuit breaker more rapidly by means of the heat accumulator. The average thermal power of thermal energy per unit time at a specific temperature is greater by a factor f, in particular compared to the thermal power which can be dissipated by the lines and the printed circuit board, where the factor f is f≧1.2, in particular f≧1.8, preferably f≧2.5 and particularly preferably f≧4.0. Furthermore, the heat accumulator which is thermally connected to the circuit breaker allows the heat which is produced by the ohmic resistor of the circuit breaker to be dissipated. In particular, the circuit breaker is heated considerably more slowly, and therefore blocking of the drive unit can be detected in good time, for example by monitoring software, using a suitable sensor system, before the circuit breaker can assume a critical temperature, since emergency switch-off can be performed even at relatively low temperatures of the circuit breaker.

The heat accumulator is produced predominantly from a metal material, and therefore heat can be transported into the interior of the heat accumulator particularly rapidly. This leads to improved distribution of the heat in the heat accumulator, and therefore the average external temperature of the heat accumulator rises correspondingly more slowly and, when the drive unit is in the blocked state, a high temperature gradient from the circuit breaker to the heat accumulator is maintained for a particularly long time. The heat accumulator, in particular, substantially comprises copper or copper alloys.

In particular, the heat accumulator has a compact, solid geometry, as a result of which the individual subregions of the heat accumulator are in good thermal contact with one another. This facilitates heat distribution within the heat accumulator, and therefore high external temperatures are avoided. In addition, bottlenecks, which have a high heat transport flow rate compared to the other regions of the heat accumulator, are avoided.

The accumulator is particularly preferably substantially cuboidal, as a result of which a compact structure which is particularly easy to produce is possible, it being possible to arrange said structure on a common printed circuit board, such that it is in thermal contact with the circuit breaker, in a particularly simple manner.

In particular, the heat accumulator has a higher thermal conductivity than the average thermal conductivity of the circuit breaker. On account of the higher thermal conductivity of the heat accumulator, the heat can be discharged particularly rapidly from the circuit breaker to the heat accumulator.

In particular, the heat accumulator can be produced by soldering, in particular accumulation of solder material. This permits particularly simple production since, for example, when the required electrical lines are soldered onto a printed circuit board, the heat accumulator can be produced by a certain area being provided with a conductor track several times, this therefore resulting in several layers of conductor tracks which form the solid and compact heat accumulator.

The circuit breaker and the heat accumulator are preferably connected to a common printed circuit board, and, in particular, the circuit breaker is connected to the heat accumulator via an electrical line. As a result, the electrical line can, at the same time, take on the function of a heat conductor, and the heat which is produced in the circuit breaker can be discharged to the heat accumulator which is preferably arranged at a distance. An insulating connection between the heat accumulator and the circuit breaker is not required. Furthermore, the printed circuit board itself can absorb some of the heat and give off said heat to the surrounding area by means of natural convection via its comparatively large surface.

In particular, the circuit breaker can have a field-effect transistor, in particular a MOSFET. As a result, a cost-effective circuit breaker can be formed. In particular, a circuit breaker with a positive temperature coefficient can be provided compared to bipolar transistors, said circuit breaker heating up and experiencing relatively high-value resistance at an excessive current when the drive unit is in the blocked state. This leads to automatic limiting of the current until the circuit breaker cools down again, the thermally connected heat accumulator preventing excessive heating.

A signal line is particularly preferably provided, this signal line signaling that the drive unit is blocked, it being possible for a signal to be applied to the signal line, in particular, as a function of the temperature of the heat accumulator. As a result, it is not necessary to monitor the drive unit itself but to provide an integrated circuit which is simple to implement. In particular, use is made here of the temperature of the heat accumulator being a measure of a blocked drive unit, with brief blockages which do not require any servicing measures automatically being ignored.

The invention also relates to a drive arrangement for operating a wiper system of a motor vehicle, having a drive unit for driving at least one wiper, and having a power circuit, which is connected to the drive unit, for controlling the drive unit, it being possible for the power circuit to be formed and developed as described above. The circuit breaker can be designed with a higher resistance and the drive arrangement can be designed at a lower cost with the aid of the heat accumulator which is thermally connected to the circuit breaker.

### BRIEF DESCRIPTION OF THE DRAWINGS

The invention will be explained in greater detail below using a preferred exemplary embodiment with reference to the appended drawing, in which:

FIG. 1 shows a schematic sectional view through a circuit according to the invention.

### DETAILED DESCRIPTION

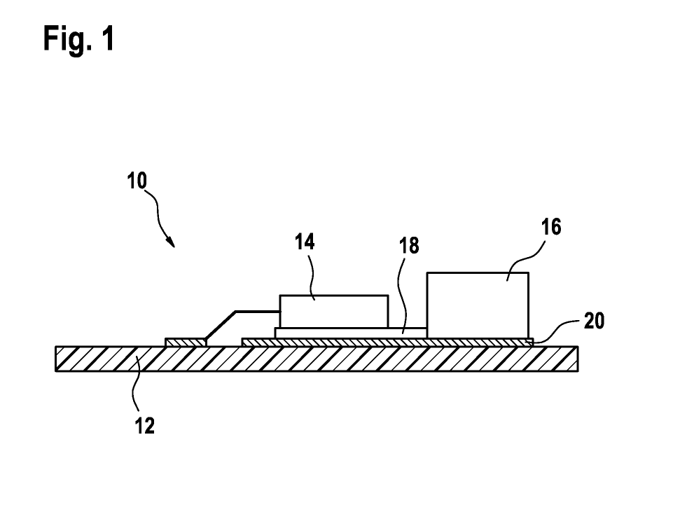

The power circuit 10 illustrated in FIG. 1 has a printed circuit 12 which has connected to it a circuit breaker 14, for example MOSFET. Furthermore, a heat accumulator 16 in the form of a copper cube is also connected to the printed circuit 12. In this case, the heat accumulator can be arranged on the same side of the printed circuit board 12 on which the circuit breaker 14 is arranged, and/or on the side of the printed circuit 12 which is averted from the circuit breaker 14. The heat accumulator 16 is arranged at a distance from the circuit breaker 14, which switches a drive unit (not illustrated) of a wiper system of a motor vehicle, and is thermally connected to the circuit breaker 14 via a heat conductor 18 and/or a conductor track 20. In the event of the sudden development of heat in the circuit breaker 14, a large portion of the produced heat can be rapidly dissipated to the heat accumulator 16, and therefore the circuit breaker 14 can be designed to be smaller in such a way that the circuit breaker 14 can be configured with a higher resistance and thus in a more cost-effective manner.

1. A power circuit for controlling a drive unit for a wiper system of a motor vehicle, having
a circuit breaker (14) for controlling the drive unit,
characterized in that
a heat accumulator (16) for absorbing heat which is produced in the circuit breaker (14) when the drive unit is in the blocked state is thermally connected to the circuit breaker (14).

2. The power circuit as claimed in claim 1, characterized in that the heat accumulator (16) is produced predominantly from a metal material.

3. The power circuit as claimed in claim 1, characterized in that the heat accumulator (16) has a compact, solid geometry.

4. The power circuit as claimed in claim 1, characterized in that the heat accumulator (16) is substantially cuboidal.

5. The power circuit as claimed in claim 1, characterized in that the heat accumulator (16) has a higher thermal conductivity than the average thermal conductivity of the circuit breaker (14).

6. The power circuit as claimed in claim 1, characterized in that the heat accumulator (16) is produced by soldering.

7. The power circuit as claimed in claim 1, characterized in that the circuit breaker (14) and the heat accumulator (16) are connected to a common printed circuit board (12).

8. A power circuit as claimed in claim 1, characterized in that the circuit breaker (14) has a field-effect transistor.

9. The power circuit as claimed in claim 1, characterized in that a signal line is provided, this signal line signaling that the drive unit is blocked, it being possible for a signal to be applied to the signal line.

10. A drive arrangement for operating a wiper system of a motor vehicle, having a drive unit for driving at least one wiper and having a power circuit (10), which is connected to the drive unit, as claimed in claim 1 for controlling the drive unit.

11. The power circuit as claimed in claim 1, characterized in that the heat accumulator (16) is produced by accumulation of solder material.

12. The power circuit as claimed in claim 1, characterized in that the circuit breaker (14) is connected to the heat accumulator (16) via an electrical line (20).

13. A power circuit as claimed in claim 1, characterized in that the circuit breaker (14) has a MOSFET.

14. The power circuit as claimed in claim 1, characterized in that a signal line is provided, this signal line signaling that the drive unit is blocked, it being possible for a signal to be applied to the signal line as a function of the temperature of the heat accumulator (16).

15. The power circuit as claimed in claim 2, characterized in that the heat accumulator (16) has a compact, solid geometry.

16. The power circuit as claimed in claim 15, characterized in that the heat accumulator (16) is substantially cuboidal.

17. The power circuit as claimed in claim 16, characterized in that the heat accumulator (16) has a higher thermal conductivity than the average thermal conductivity of the circuit breaker (14).

18. The power circuit as claimed in claim 17, characterized in that the heat accumulator (16) is produced by soldering.

19. The power circuit as claimed in claim 18, characterized in that the circuit breaker (14) and the heat accumulator (16) are connected to a common printed circuit board (12).

20. A power circuit as claimed in claim 19, characterized in that the circuit breaker (14) has a field-effect transistor.

21. The power circuit as claimed in claim 20, characterized in that a signal line is provided, this signal line signaling that the drive unit is blocked, it being possible for a signal to be applied to the signal line.
